(19) United States
(12) Patent Application Publication
(10) Pub. No.: US 2013/0284369 A1
(43) Pub. Date: Oct. 31, 2013

(54) TWO-PHASE OPERATION OF PLASMA CHAMBER BY PHASE LOCKED LOOP

(71) Applicant: APPLIED MATERIALS, INC., Santa Clara, CA (US)

(72) Inventors: Satoru Kobayashi, Santa Clara, CA (US); Lawrence Wong, Fremont, CA (US); Jonathan Liu, Sunnyvale, CA (US); Yang Yang, Sunnyvale, CA (US); Kartik Ramaswamy, San Jose, CA (US); Shahid Rauf, Pleasanton, CA (US); Shane C. Nevil, Livermore, CA (US); Kallol Bera, San Jose, CA (US); Kenneth S. Collins, San Jose, CA (US)

(73) Assignee: APPLIED MATERIALS, INC., Santa Clara, CA (US)

(21) Appl. No.: 13/632,302

(22) Filed: Oct. 1, 2012

Related U.S. Application Data
(60) Provisional application No. 61/638,846, filed on Apr. 26, 2012.

(51) Int. Cl. C23C 16/505; B05C 9/00

(52) U.S. Cl. CPC C23C 16/505; B05C 9/00
USPC 156/345.26; 118/712

(57) ABSTRACT

Plasma distribution is controlled in a plasma reactor by controlling the phase difference between opposing RF electrodes, in accordance with a desired or user-selected phase difference, by a phase-lock feedback control loop.

### CROSS-REFERENCE TO RELATED APPLICATIONS

This application claims the benefit of U.S. Provisional Application Ser. No. 61/638,846, filed Apr. 26, 2012 entitled TWO-PHASE OPERATION OF PLASMA CHAMBER BY PHASE LOCKED LOOP, by Satoru Kobayashi, et al.

### BACKGROUND OF THE INVENTION

Plasma processing of a workpiece in the fabrication of integrated circuits, plasma displays, solar panels or the like requires uniform treatment of each workpiece across its surface. For example, in plasma processing of semiconductor wafers, feature sizes are on the order of nanometers, and uniformity and control of plasma ion distribution density across the workpiece surface is critical. Uniformity of distribution of etch rate or deposition rate across the surface of workpiece is required, as workpiece size (e.g., semiconductor wafer diameter) is increasing, and feature sizes are decreasing. Nora-uniformity in plasma processing can arise from non-uniformities or asymmetries in the reactor chamber electrical characteristics, non-uniformity in the distribution of process gases and flow rates, or non-uniformity in the application of RF power, for example. It is necessary to correct or compensate for such non-uniformities.

### SUMMARY

A plasma reactor for processing a workpiece includes a vacuum chamber, a workpiece support pedestal in the chamber having a workpiece support surface, a top electrode overlying the workpiece support surface and a bottom electrode underlying the workpiece support surface. Top and bottom RF power amplifiers are coupled to the top and bottom electrodes respectively. A clock signal source is coupled to the top and bottom RF power amplifiers, and a phase shifter is coupled between the clock signal source and at least one of the top and bottom RF power amplifiers, the phase shifter having a phase shifter control input. Top and bottom RF sensor probes, such as voltage probes, for example, are coupled to (or placed near) the top and bottom electrodes, respectively. A phase detector has respective inputs coupled to the top and bottom RF sensor probes and has an output. A user interface has an output defining a user-selected phase difference between the top and bottom sensor probes. A feedback controller has respective inputs coupled to the output of the phase detector and the output of the user interface. The feedback controller further has a feedback controller output coupled to the phase shifter control input.

The phase detector includes a frequency down conversion stage having respective inputs coupled to the RF sensor probes and respective outputs, and a phase comparator having an output and a pair of inputs coupled to the respective outputs of the frequency down conversion stage. In one embodiment, an integrator is coupled between the controller output and the phase shifter control input. The feedback controller is adapted to produce successive correction signals at the feedback controller output, and the integrator is adapted to provide to the phase shifter control input an average over n of the previous successive correction signals. In one embodiment, the successive correction signals correspond to a sampling period T, and wherein T is less than a settling time of one of the impedance matches by a factor greater than 10.

In one embodiment, the phase comparator includes respective sine wave-to-square wave converters coupled to the respective outputs of the frequency down conversion stage, and a phase lock loop phase comparator coupled to the respective sine wave-to-square wave converters. In another embodiment, the phase comparator comprises an IQ demodulator.

If two sets of top and bottom RF generators of different frequencies are present, then two phase detectors and two user interface outputs are compared to control two phase shifters controlling the two sets of generators. In this embodiment, either two feedback controllers are employed or a single feedback controller is multiplied between two sets of inputs arid outputs.

### BRIEF DESCRIPTION OF THE DRAWINGS

So that the manner in which the exemplary embodiments of the present invention are attained and can be understood in detail, a more particular description of the invention, briefly summarized above, may be had by reference to the embodiments thereof which are illustrated in the appended drawings. It is to be appreciated that certain well known processes are not discussed herein in order to not obscure the invention.

FIGS. 1A and 1B constitute a schematic block diagram of a first embodiment of a plasma reactor for controlling radial distribution of plasma ions, by the phase difference between top and bottom electrodes, in which an RF power generator coupled to a bottom electrode is slaved to an RF power generator coupled to a top electrode.

FIG. 1C is an enlarged view of a portion of FIG. 1A.

FIG. 2 is a schematic block diagram of a modification of the phase detector in the embodiment of FIGS. 1A and 1B employing an I-Q demodulator as a phase comparator.

FIGS. 3A and 3B constitute a schematic block diagram of an embodiment, in which an RF power generator coupled, to a top electrode is slaved to an RF power generator coupled to a bottom electrode.

FIGS. 4A and 4B constitute a schematic block diagram of an embodiment, in which RF power generators coupled to the top and bottom electrodes are both synchronized to a common clock having different phase-controlled outputs.

FIGS. 5A, 5B and 5C constitute a schematic block diagram of an embodiment for controlling the phase differences among pairs of RF signals of different frequencies.

FIGS. 6A, 6B and 6C constitute a schematic block diagram of an embodiment employing a pair of independent feedback controllers.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

The plasma reactor described herein provides control of radial distribution of plasma ion density by controlling the phase difference between RF source power waveforms applied to opposing RF source power applicators above and below the surface of the workpiece being treated. In the description that follows, the opposing RF source power applicators are opposing electrodes. The RF power distribution at the surface of the workpiece affects plasma ion density, which in turn affects process rate distribution. The process may be an etch process or a deposition process, for example.

In general, RF power of the same frequency is applied to the two opposing electrodes. Maintaining a phase difference of 180° between the RF waveforms applied to the opposing electrodes causes the electric field lines to extend in a generally straight manner between the opposing electrodes, resulting in a center-high (edge-low) radial distribution of plasma ion density at the workpiece surface. Maintaining a phase difference of 0° between the RF waveforms applied to the opposing electrodes causes the electric field lines to extend in a radial direction from each of the opposing electrodes to the grounded side wall of the chamber enclosure, resulting in an edge-high (center-low) radial distribution of plasma ion density at the workpiece surface. In principle, the user should be able to select any degree of center-high or edge-high radial distribution of the plasma by selecting any phase angle or phase difference of the two electrodes in the range of 0° to 180°, and thereby reduce any observed non-uniformity in process rate distribution on the treated surface of the workpiece.

Measuring the phase difference between the top and bottom electrodes is most easily done taking measurements at the RF power generator output to the electrode. Such a measurement is typically inaccurate, because there is an RF impedance match circuit in the path to the electrode, which distorts the measurement.

One problem is that it is difficult to control the phase difference manually when the process recipe requires fast adjustment of the phase difference. The problem could be addressed by providing a feedback control loop responsive to a selection of the desired phase difference at a user interface. However, we have discovered that such a feedback control loop can be unreliable or unstable when responding to a phase difference between power waveforms of very high frequency on the opposing electrodes. Other sources of instability can lead to “dead-zones” in the 0° to 360° phase angle range, in which the feedback control loop cannot reach or hold a phase angle within the dead-zone.

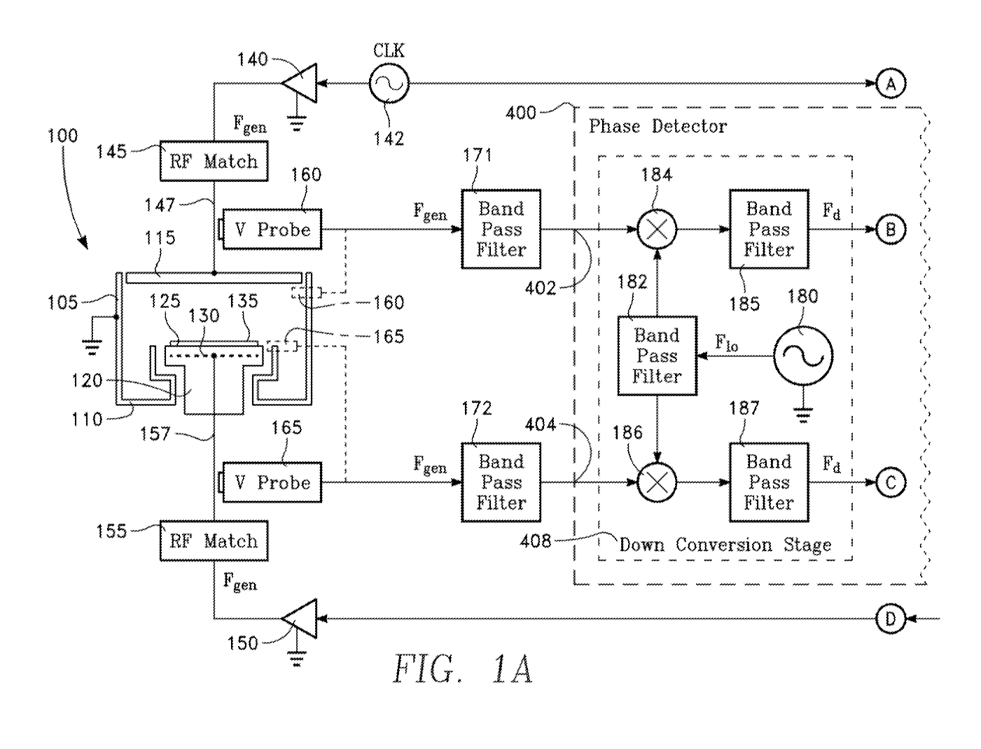

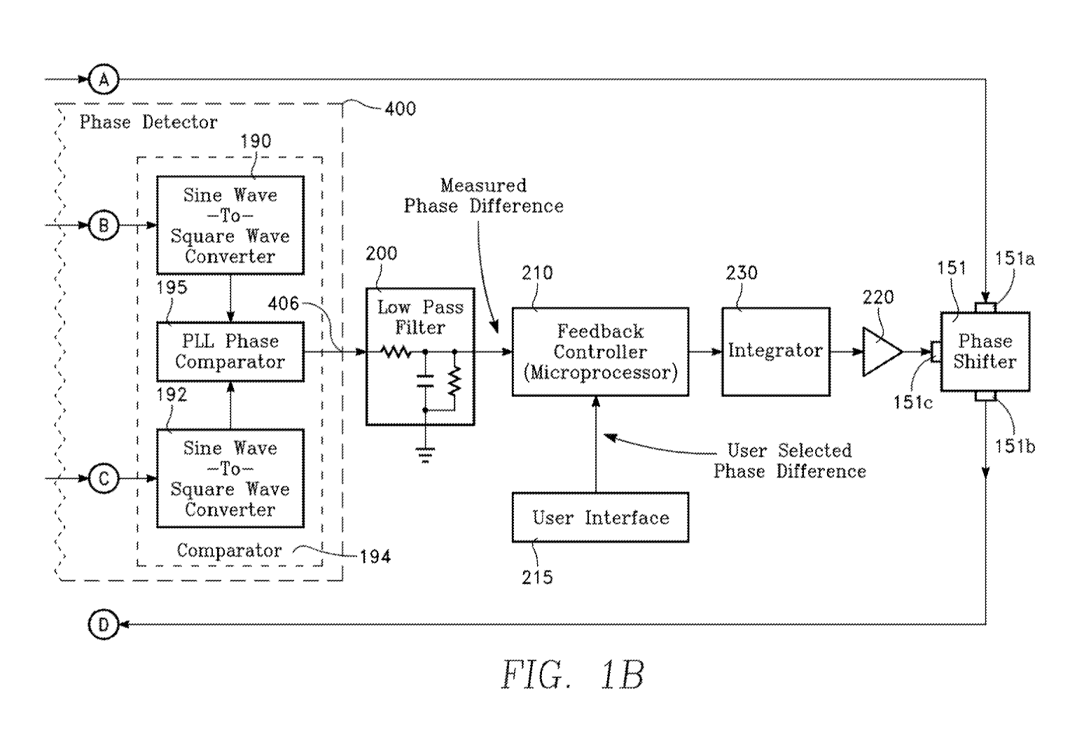

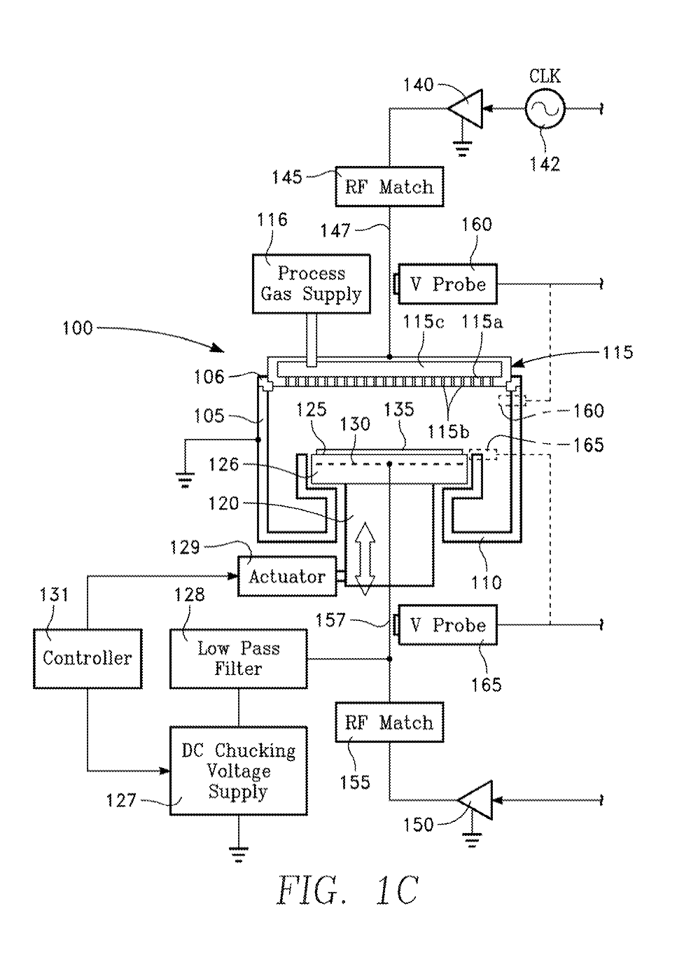

Referring to FIGS. 1A and 1B, a plasma reactor includes vacuum chamber enclosure 100 that includes a cylindrical side wall 105, a floor 110, and a ceiling electrode 115. A pedestal 120 extends through the floor 110 and holds a workpiece support 125 including a workpiece support electrode 130 underlying a workpiece support surface at the top of the workpiece support and facing the ceiling electrode 115. A workpiece such as semiconductor wafer 135 may be held on the workpiece support surface of the workpiece support 125. Not shown in the drawings are gas injection and gas distribution apparatus of the reactor chamber 100, an exhaust port in the floor 110 and a vacuum pump coupled to the exhaust port.

As shown in the enlarged view of FIG. 1C, the ceiling electrode 115 is a gas distribution plate including bottom layer 115a having an array of gas injection orifices 115b, and an overlying gas manifold layer 115c. A process gas supply 116 is coupled to the gas manifold layer 115c. As also shown in FIG. 1C, the workpiece support 125 embodies an electrostatic chuck, including an insulating puck 126 in which the electrode 130 is embedded. A D.C. chucking voltage supply 127 is connected through a low pass isolation filter 128 to the electrode 130. The electrode 130 functions as an electrostatic chucking electrode as well as an electrode through which RF bias power from the bottom RF amplifier 150 is coupled to the plasma. The workpiece support 125 is may be raised toward the ceiling electrode 115 or depressed away from the ceiling electrode so as to controllably vary the workpiece-to-ceiling gap. For this purpose, an actuator 129 coupled to the workpiece support raises and depresses the workpiece support 125. A process controller 131 may govern the actuator 129 and the D.C. voltage supply 127.

A top RF power amplifier 140 is synchronized with the output of a clock or oscillator 142. The top RF power amplifier 140 is coupled to the ceiling electrode 115 through a top RF impedance match circuit 145 by a top coaxial feed 147. A bottom RF power amplifier 150 of the same frequency as the top RF power amplifier 140, is coupled through a bottom RF impedance match circuit 155 to the workpiece support electrode 130 by a bottom coaxial feed 157. The top and bottom RF power amplifiers 140 and 150 output the same frequency, Fgen, which may be a VHP frequency suitable for a capacitively coupled plasma source. The bottom RF power amplifier 150 is synchronized to the clock 142 through a controllable phase shifter 151. The phase shifter 151 receives the signal from the clock 142 at its input port 151a and provides at its output port 151b a phase-shifted version of the output of the clock 142. The amount by which the signal at the output port 151b is phase-shifted from the signal at the input port 151a is determined by the phase shifter 151 in accordance with a control signal applied to its control input 151c. Control of the phase shifter 151 will be described in detail later herein. The term “phase shifter” as used in this specification includes any suitable device capable of shifting phase of an RF or oscillator signal in response to a control signal. Such a device may be a passive or active device, and may be implemented with passive variable reactance elements or active RF circuits or digital circuits, for example.

The side wall 105 is conductive and is connected to ground. The side wall 105 functions as a third electrode to the ceiling and workpiece support electrodes 115 and 130.

A top RF sensor probe 160 is placed near or on the ceiling electrode 115. The top RF sensor probe 160 may be of the type disclosed in related U.S. Patent Application Publication No. US-2012-0086464-A1 published Apr. 12, 2012 entitled IN-SITU VHF VOLTAGE/CURRENT SENSORS FOR A PLASMA REACTOR, by Hiroji Hanawa, et al. The RF sensor probe 160 may be an RF voltage probe or an RF sensor probe or other suitable probe. If the top RF sensor probe 160 is an RF voltage probe, then the top RF sensor probe 160 has a floating electrode in its sensor head that may be coupled to the center conductor of the top coaxial feed 147. Alternatively, for a sufficiently low frequency range (e.g., below 1 MHz) the floating electrode of the top RF sensor probe 160 may be coupled to the ceiling electrode, in which case the probe 160 may be on either side of the ceiling electrode 115 (i.e., either inside or outside of the enclosure 100), as indicated in dashed line in FIG. 1A. Placement of the RF sensor probe 160 close to the ceiling electrode 115 in this manner provides accurate measurement without distortion by the impedance match 145. Otherwise, for frequencies above 1 MHz, the measurement should be taken inside the coaxial top feed 147.

A bottom RF sensor probe 165 is placed near the workpiece support electrode 130 or is coupled to the center conductor of the bottom coaxial feed 157. The bottom RF sensor probe 165 may be of the same type as the top RF sensor probe 160. The bottom RF sensor probe 165 has a floating electrode in its sensor head that may be coupled to the center conductor of the bottom coaxial feed 157. Alternatively, for a low frequency range (e.g., below 1 MHz), the floating electrode of the bottom RF sensor probe 165 may be coupled to the workpiece support 125 or electrode 130, in which case the probe 165 may be inside the enclosure 100, as indicated in dashed line in FIG. 1A. Placement of the RF sensor probe 165 close to the workpiece support electrode 130 in this manner provides accurate measurement without distortion by the impedance match 155.

If the bottom RF sensor probe 165 is coupled to the RF feed 157 at a significant distance from the support electrode 130, then a transform processor (not illustrated) may be used to improve accuracy of the measurement. The unillustrated transform processor provides a correction of the signal from the bottom RF sensor probe 165 to compensate for differences attributable to the distance between the bottom RF sensor probe 165 and the workpiece support electrode 130.

A pair of bandpass filters 171, 172 remove noise (such as noise attributable to plasma sheath harmonics) from the signals output by the RF sensor probes 160, 165 respectively. The phase detector 400 may include an optional down conversion stage 408 including a crystal-controlled local oscillator 180 having an output frequency Flo which differs from the RF power generator frequency Fgen of the top and bottom RF power amplifiers 140 and 150 by a difference frequency Fd. A bandpass filter 182 removes all but the local oscillator frequency Flo from the output of the local oscillator 180. The down conversion stage 408 further includes top and bottom channel mixers 184 and 186. The top channel mixer 184 combines the outputs of the top RF sensor probe 160 (filtered by the band pass filter 171) and the local oscillator 180 (filtered by the band pass filter 182) to produce a modulated top channel signal. A band pass filter 185 extracts the lower sideband (the difference frequency Fd) from the modulated top channel signal. The bottom channel mixer 186 combines the outputs of the bottom RF sensor probe 165 (filtered by the band pass filter 172) and the local oscillator 180 (filtered by the band pass filter 182) to produce a modulated bottom channel signal. A band pass filter 187 extracts the lower sideband (the difference frequency Fd) from the modulated bottom channel signal.

The outputs of the band pass filters 185 and 187 represent outputs of the top and bottom RF sensor probes 160 and 165 that have been down-converted in frequency (i.e., from Fgen to Fd). The RF power generator frequency Fgen may be a VHF frequency, while the down-converted frequency Fd may be in the medium frequency (MF) or low frequency (LF) band, for example. It should be noted that the down-conversion stage 408 may not be necessary in many applications and may be eliminated if desired.

The phase detector 400 further includes a phase comparator 194. In a first embodiment, the phase comparator 194 includes sine wave-to-square wave converters 190 and 192 and a phase lock loop (PLL) phase comparator 195. The down-converted version of the top RF sensor probe output (from the band pass filter 185) is converted to a square wave signal by the sine wave-to-square wave converter 190. The down-converted version of the bottom RF sensor probe output (from the band pass filter 187) is converted to a square wave signal by the sine wave-to-square wave converter 192. The PLL phase comparator 195 measures the phase difference between the signals produced by the pair of sine wave-to-square wave converters 190 and 192. The phase comparator 195 produces a phase difference signal representing the measured phase difference, which represents the phase angle between the outputs of the top and bottom RF sensor probes 160 and 165.

A low pass filter 200 filters the phase difference signal, and functions as a feedback loop filter. A feedback controller 210, which may be implemented as a microprocessor, senses a difference between the phase difference signal from the low pass filter 200 and a user-selected phase difference. The user-selected phase difference may be furnished to the feedback controller 210 from a user interface 215, such as a personal computer or other device having a keyboard or touch-sensitive screen or other input device. The feedback controller 210 produces a signal representing an error or difference between the user-selected phase difference (from the user interface 215) and the measured phase difference (from the phase comparator 195). This error signal is applied as corrective (negative) feedback to the control input 151c of the phase shifter 151. For example, if the measured phase difference is greater than the user-selected phase difference, then the error signal is applied to the control input 151c of the phase shifter 151 so as to decrease the phase difference established by the phase shifter 151. Similarly, if the measured phase difference is less than the user-selected phase difference, then the error signal is applied to the control input 151c of the phase shifter 151 so as to increase the phase difference established by the phase shifter 151. The error signal provided by the feedback controller 210 may be either an analog voltage or a digital signal, depending upon the design of the phase shifter 151.

The range of the voltage at the phase shifter control input required to swing the phase shifter 151 through the range of phase angles 0° through 360° may differ from the voltage range produced by the feedback controller 210 for these same angles. Therefore, an operational amplifier 220 may be employed at the output of the feedback controller 210 to provide the appropriate shift in voltage range.

The system of FIGS. 1A and 1B is a feedback control loop, in which the measured phase difference is compared to a user-selected phase difference by the feedback controller 210, which provides negative feedback to the phase shifter 151. In the described, embodiment, the phase comparator 195 and the feedback controller operate in synchronism with a clock (e.g., the clock 142). The phase comparator 195 samples the outputs of the sine wave-to-square wave converters 190, 192 at a sampling rate. Each sample or iteration results in an updated error signal from the feedback controller 210, resulting in a succession of error signals. An integrator 230 may be provided at the output of the feedback controller 210. The integrator 230 may be implemented as a memory storing the last n error signals VP where the index i ranges from 1 (the current iteration) to n (the oldest iteration). The integrator 230 computes the average over the last n error signals and outputs this average to the phase shifter control input 151c or to the operational amplifier 220 if present. This averaging process improves the stability of the feedback control loop.

The rate at which the feedback controller 210 produces the succession of error signals is determined by the sampling rate r at which the controller 210 samples the output of the phase detector 400. Stability of the feedback loop over a complete range of values (e.g., 0°-360°) of the user-selected phase difference is enhanced by establishing the sampling rate r to be sufficiently great so that the time between samples T=1/r is less than the settling time (t) of either or both of the impedance matches 145, 155, preferably by a factor of 10, or 100 or 1000, for example. The settling time, t, of each impedance match is the time required for the impedance match to complete a change in impedance in response to a sensed change in load impedance on the RF amplifier, and is principally a function of the speed of stepper motors (not shown in the drawing) controlling unillustrated. variable capacitors in the impedance matches 145 and 155. For example, the settling time, t, may be measured using a variable RF load connected to the output of the impedance match, making a discrete change in the impedance of the RF load, and observing the amount of time required for the impedance match to stabilize following the change.

The frequency down-conversion provided by the local oscillator 180 and the mixers 184 and 186 reduces the frequency of the signals processed by the phase comparator 195 down to a value within the range or capability of the phase comparator 195. The phase comparator 195, the sine wave-to-square wave converters 190 and 192, the mixers 184 and 186, the band pass filters 185 and 187, the band pass filter 182 and the local oscillator 180 together constitute a phase detector 400 having first and second inputs 402 and 404 and an output 406.

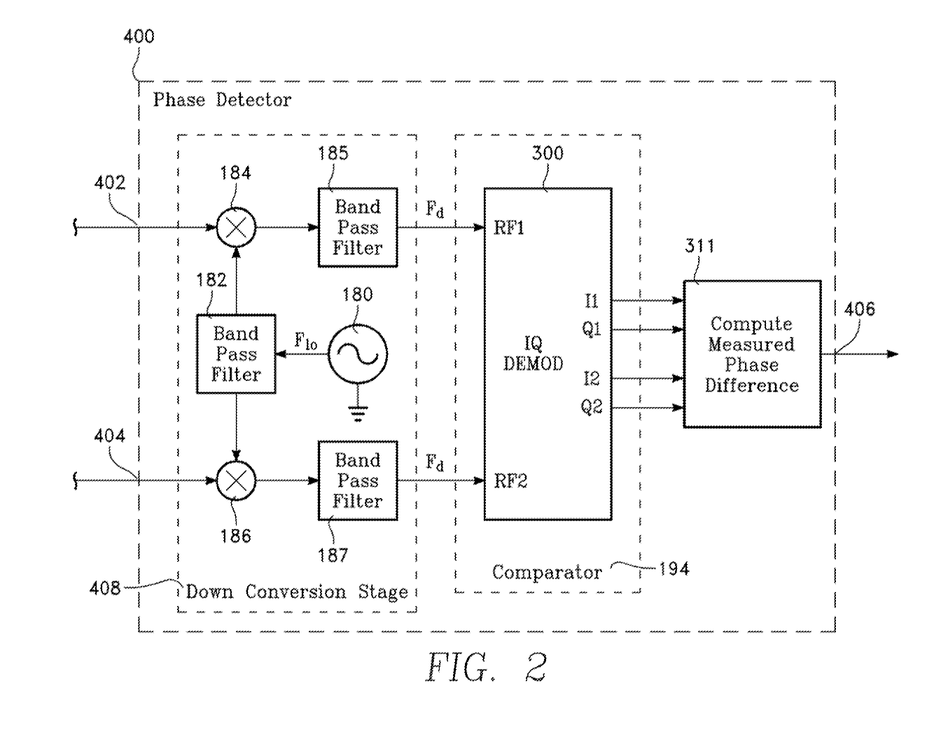

FIG. 2 depicts a modification of the phase comparator 194 of the phase detector 400 of FIGS. 1A and 1B, in which the PLL phase comparator 195 of FIG. 1B is replaced by an I-Q demodulator 300. The IQ demodulator 300 of FIG. 2 has a pair of RF inputs, RF1 and RF2, connected to the outputs of the band pass filters 185 and 187 respectively. The I-Q demodulator 300 has four outputs, namely an in-phase output I1 and a quadrature output Q1 derived from the input RF1, and an in-phase output I2 and a quadrature output Q2 derived from the input RF2. If θ₁ is the phase of the signal at RF1 and θ₂ is the phase of the signal at RF2, then I1 represents cosθ₁, Q1 represents sinθ₁, I2 represents cosθ₂, and Q2 represents sinθ₂. A computational stage 311 is adapted to compute a measured phase difference (between the outputs of the RF sensor probes 160 and 165) from the four IQ output signals I1, Q1, I2 and Q2. While FIG. 2 depicts the computational stage 311 as a component with the IQ demodulator 300, the computational stage 311 instead may be implemented inside the feedback controller 210. The sine wave-to-square wave converters 190, 192 of FIG. 1B are eliminated in the embodiment of FIG. 2.

The frequency down-conversion provided by the local oscillator 180 and the mixers 184 and 186 reduces the frequency of the signals processed by the IQ demodulator 300 down to a value within the range or capability of the IQ demodulator 300.

In the embodiments of FIGS. 1A-1B and FIG. 2, the clock 142 directly controls the top RF power amplifier 140, and the bottom RF power amplifier 150 is slaved to the clock of the top RF power amplifier 140, through a phase-shifted version of the clock signal, as has been described above. in such an embodiment, the clock 142 is connected to the input port 151a of the phase shifter 151, while the output port 151b of the phase shifter 151 governs the bottom RF power amplifier 150.

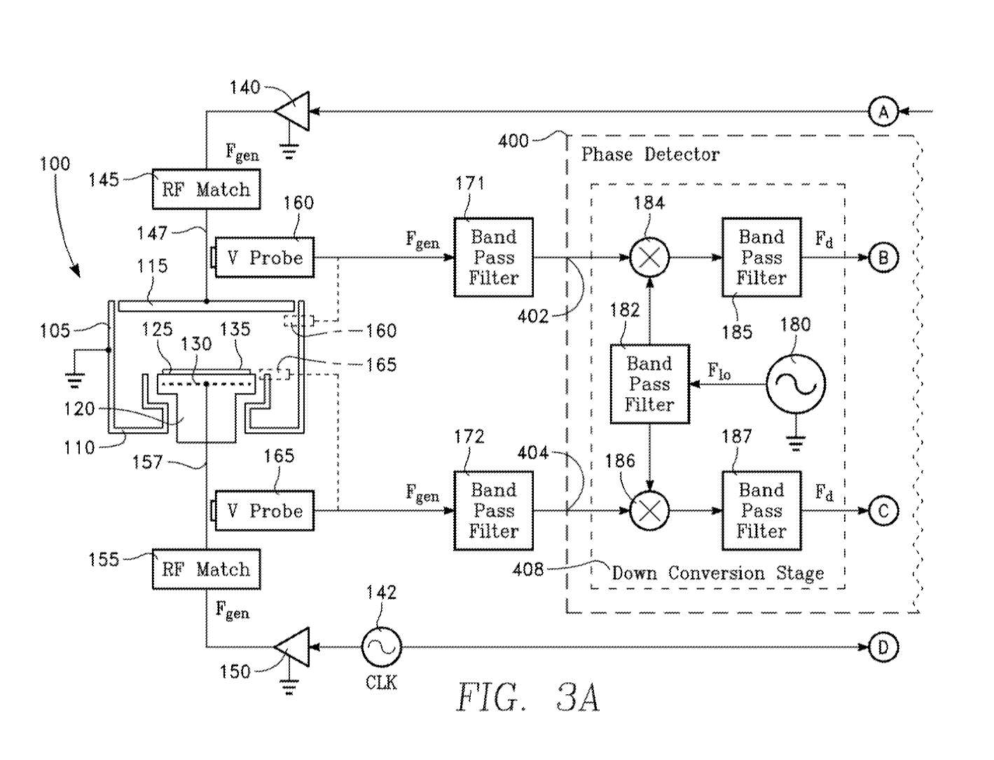

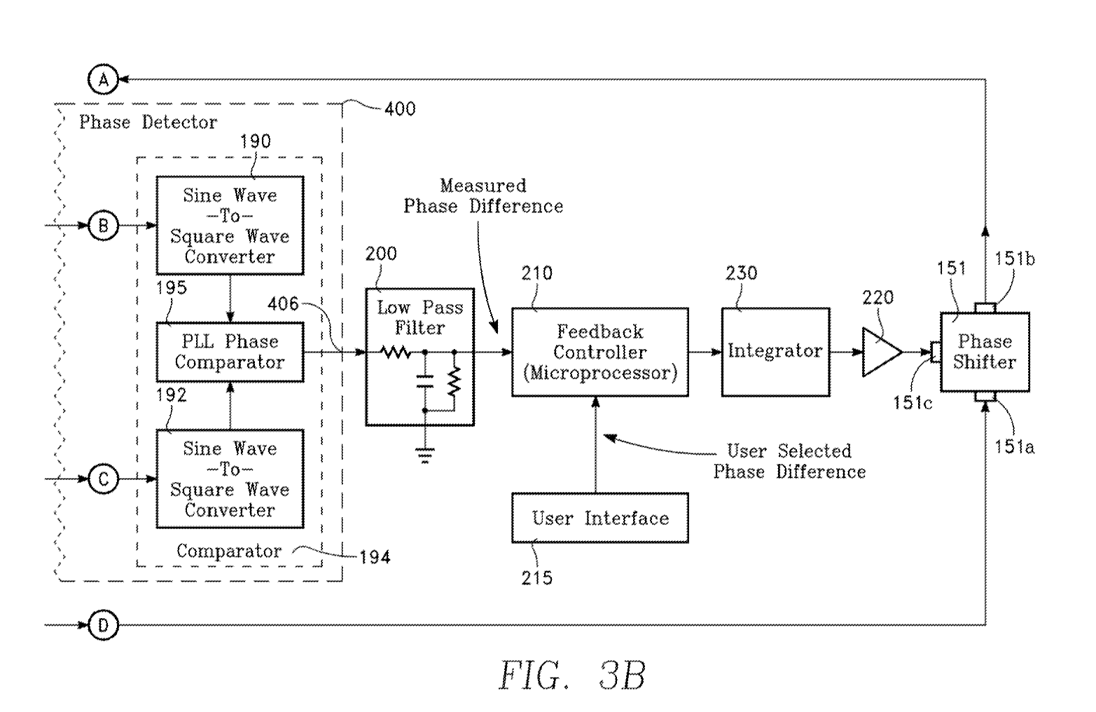

FIGS. 3A and 3B depict a modification in which the clock 142 directly controls the bottom RF power amplifier 150, and the top RF power amplifier 140 is slaved to the clock of the bottom RF power amplifier 150, through a phase-shifted version of the clock signal. In the embodiment of FIGS. 3A and 3B, the clock 142 is connected to the input port 151a of the phase shifter 151, while the output port 151b of the phase shifter 151 governs the top RF power amplifier 140. The phase detector 400 of FIGS. 3A and 3B is depicted as including the down conversion stage 408 followed by a phase comparator which may be the PLL phase comparator 195 of FIG. 1B or the IQ demodulator 300 of FIG. 2.

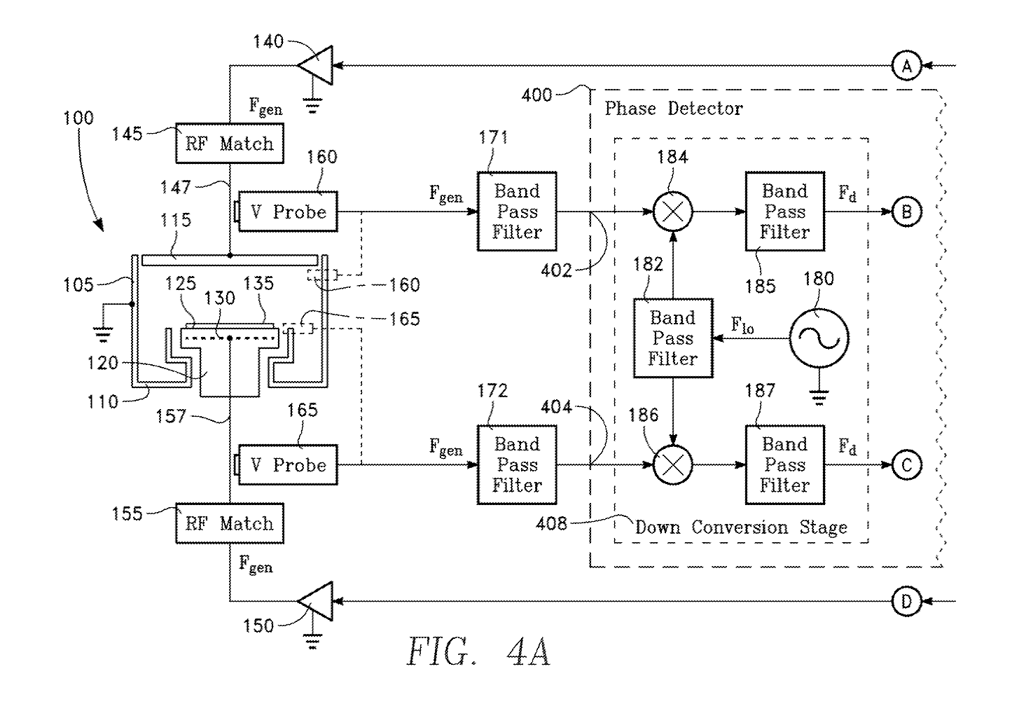

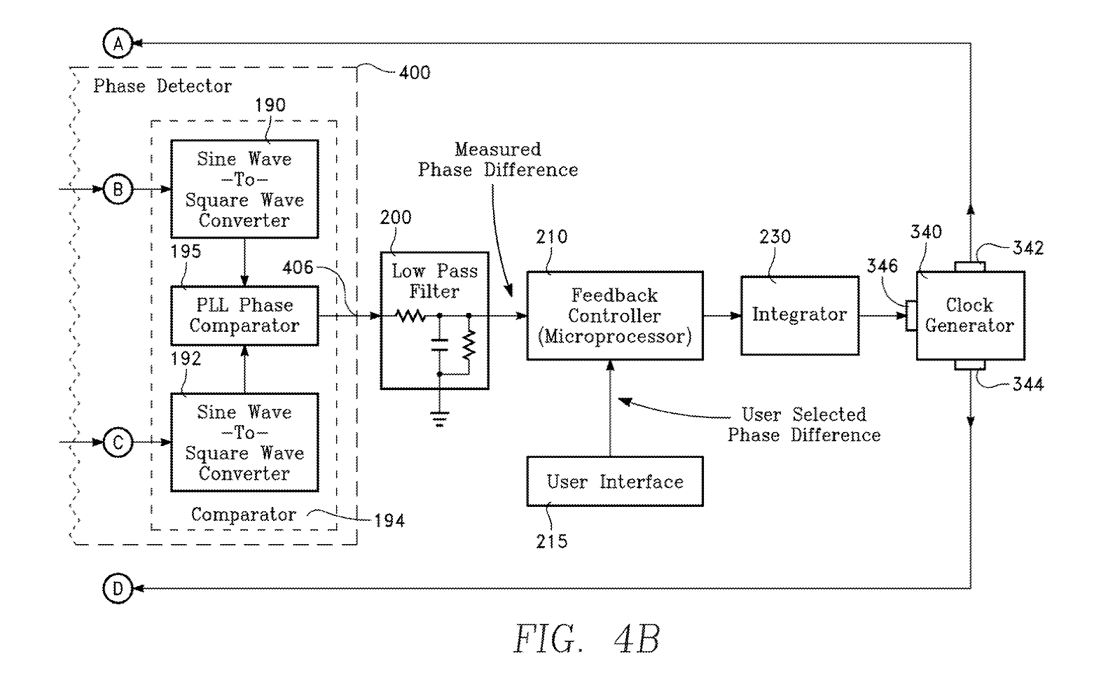

In the foregoing embodiments, one of the two RF power amplifiers 140 and 150 is controlled directly by the clock 142, while the other is slaved to a phase-shifted version of the clock signal. FIGS. 4A and 4B depict an embodiment in which the phase shifter 151 is replaced by a two-port exciter or clock generator 340 having a pair of clock outputs 342 and 344 whose phases are separately controllable. For example, the clock generator 340 can be implemented as two sets of IQ modulators. The clock generator 340 controls the phase difference between the two clock outputs 342, 344 in accordance with a signal applied to a control input 346. The clock output 342 is connected to a clock input of the top RF power amplifier 140, and the clock output 344 is connected to a clock input of the bottom RF power amplifier 150. The output of the feedback controller 210 is coupled to the control input 346 of the clock generator.

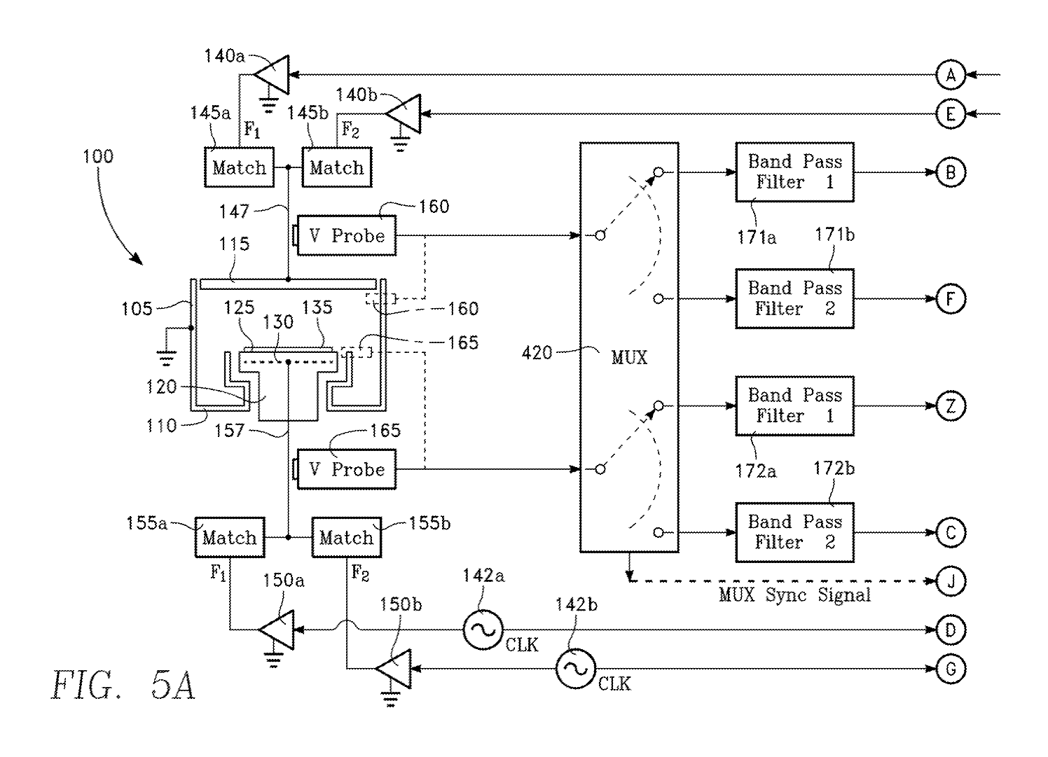

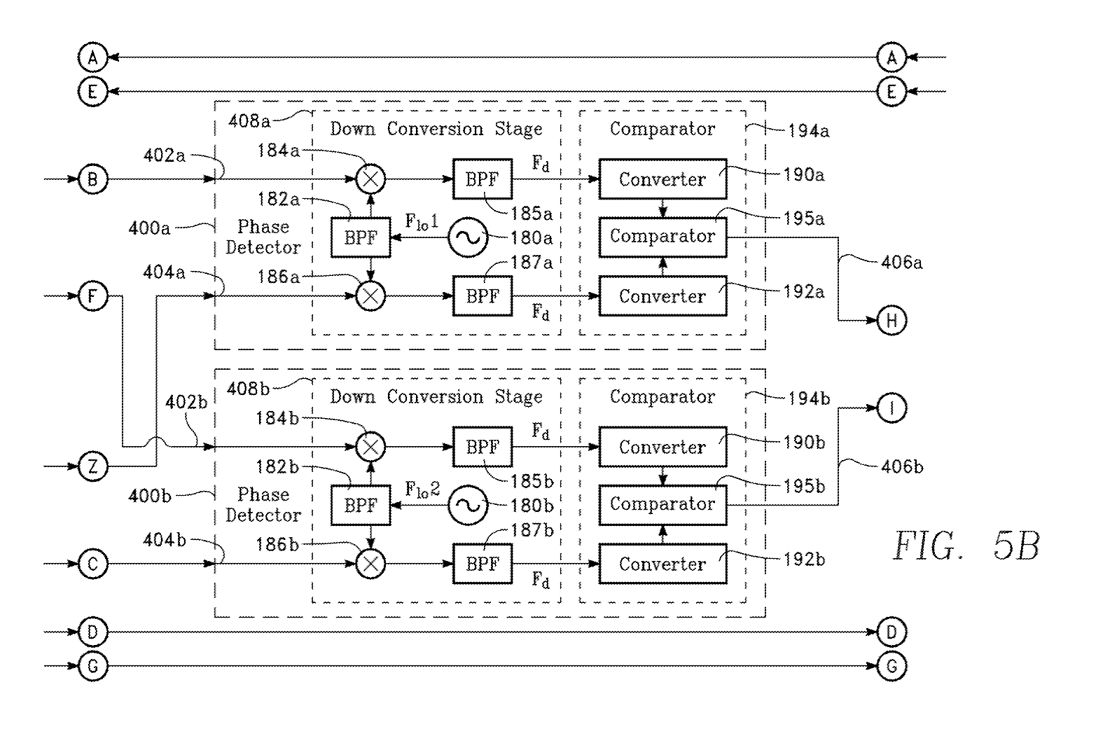

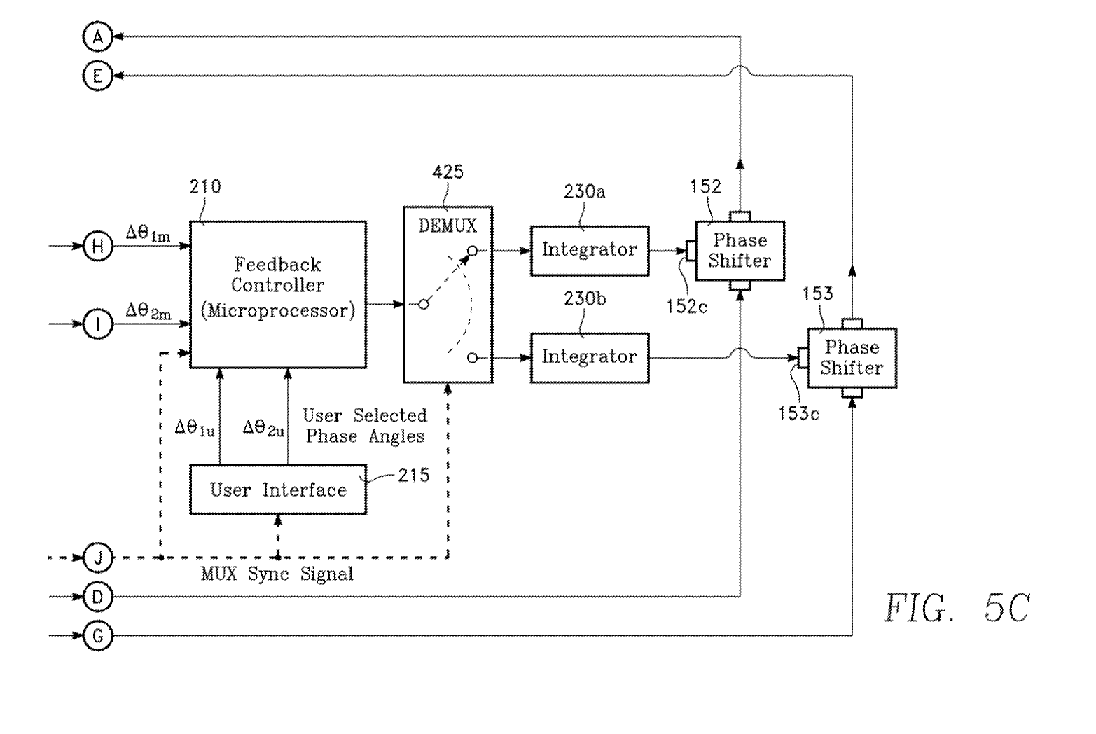

FIGS. 5A, 5B and 5C depict an embodiment for independently controlling different phase angles between different pairs of RF power generators of different frequencies, F1 and F2, coupled to the ceiling and workpiece support electrodes 115 and 130. Two pairs of top and bottom RF power generators are coupled to the ceiling and workpiece support electrodes 115 and 130. Specifically, a first pair of RF power generators, including a first top RF power amplifier 140a and a first-bottom RF power amplifier 150a, both having the same RF frequency F1, are coupled to the ceiling and workpiece support electrodes 115 and 130, respectively, through respective RF impedance matches 145a and 155a. Similarly, a second pair of RF power generators, including a second top RF power amplifier 140b and a second bottom RF power amplifier 150b, both having the same RF frequency F2, are coupled to the ceiling and workpiece support electrodes 115 and 130, respectively, through respective RF impedance matches 145b and 155b. A first pair of top and bottom bandpass filters 171a and 172a are coupled to the top and bottom RF sensor probes 160 and 165, respectively, through a multiplexer 420. The bandpass filters 171a and 172a are tuned to a frequency band centered at the frequency F1 of the first pair of RF power amplifiers 140a and 150a. A second pair of top and bottom bandpass filters 171b and 172b are coupled to the top and bottom RF sensor probes 160 and 165, respectively, through the multiplexer 420. The bandpass filters 171b and 172b are tuned to a frequency band centered at the frequency F2 of the second pair of RF power amplifiers 140b and 150b.

A first phase detector 400a having inputs 402a and 404a provides at an output 406a a first measured phase difference Δθ_{1M} between the outputs of the first pair of bandpass filters 171a and 172a. A second phase detector 400b having inputs 402b and 404b provides at its output 406b a second measured phase difference Δθ_{2M} between the outputs of the second pair of bandpass filters 171b and 172b. Each of the two phase detectors 400a and 400b may be identical to the phase detector 400 of FIG. 1B or may be identical to the phase detector 400 of FIG. 2. The measured phase angle Δθ_{1M} is the phase difference between the first RF power amplifier pair 140a and 150a. The measured phase angle Δθ_{2M} is the phase difference between and the second RF power amplifier pair 140b and 150b. The feedback controller 210 receives the output signals representing Δθ_{1M} and Δθ_{2M}, one at a time, during respective time division multiplexing windows under the control of the multiplexer 420. The multiplexer 420 performs time division multiplexing of the two pairs of band pass filters 171a, 172a and 171b, 172b. Alternatively (or in addition), the multiplexer 420 may perform time division multiplexing of the signals representing Δθ_{1M} and Δθ_{2M} at the input to the feedback controller 210.

Each phase detector 400a and 400b of FIG. 5B includes a respective down conversion section 408a and 408b each similar to the down conversion stage 408 of FIG. 1B. Each phase detector 400a and 400b further includes a respective phase comparator 194a and 194b each similar to the phase comparator 194 of FIG. 1B or, in the alternative, similar to the phase detector 194 of FIG. 2. FIG. 5B depicts an embodiment in which each phase comparator 194a and 194b embodies the structure as the phase comparator 194 of FIG. 1B. As depicted in FIG. 5B, the down conversion stage 408a consists of a local oscillator 180a, a bandpass filter 182a, mixers 184a and 186a, and band pass filters 185a and 187a, arranged similarly to the down conversion stage 408 of FIG. 1A. Similarly, the down conversion stage 408b consists of a local oscillator 180b, a bandpass filter 182b, mixers 184b and 186b, and band pass filters 185b and 187b, arranged similarly to the down conversion stage 408 of FIG. 1A. As further depicted in FIG. 5B, the phase comparator 194a includes sine wave-to-square wave converters 190a and 192a and a phase comparator 195a, arranged similarly to the phase comparator 194 of FIG. 1B. Similarly, the phase comparator 194b includes sine wave-to-square wave converters 190b and 192b and a phase comparator 195b, arranged similarly to the phase comparator 194 of FIG. 1B.

The two local oscillators 180a and 180b may produce different local oscillator frequencies Flo1 and Flo2 compatible with the different RF power generator frequencies F1 and F2, respectively.

In an alternative embodiment, each phase comparator 194a and 194b may be modified in accordance with FIG. 2. In such a modification of the phase comparator 194a, the converters 190a and. 192a and the phase comparator 195a would be replaced by a first IQ demodulator similar to the IQ demodulator 300 of FIG. 2. Similarly, in such a modification of the phase comparator 194b, the converters 190b and 192b and the PLL phase comparator 195b would be replaced by a second IQ demodulator similar to the IQ demodulator 300 of FIG. 2.

The user interface 215 provides two user-selected phase angles, namely a first phase angle Δθ_{1U} representing the desired or user-selected phase difference between the upper and lower probes at the frequency of the first pair of RF power amplifiers 140a, 150a, and a second phase angle Δθ_{2U} representing the desired or user-selected phase difference between the upper and lower probes at the frequency of the second pair of RF power amplifiers 140b, 150b. The user interface 215 is synchronized with the multiplexer 420 so as to send each of the two user-selected phase differences Δθ_{1U} and Δθ_{2U} to the feedback controller 210 during alternate time division multiplexing windows.

The feedback controller 210 produces a first corrective signal in accordance with the difference between Δθ_{1M} and Δθ_{1U} during alternate time division multiplexing windows. During the remaining time division multiplexing windows, the feedback controller 210 produces a second corrective signal in accordance with the difference between Δθ_{2M} and &BzΔθ_{2U}. A demultiplexer 425 directs the first corrective signal to a control input 152c of a first phase shifter 152 during a first time division multiplexing window, and directs the second corrective signal to a control input 153c of a second phase shifter 153 during a second time division multiplexing window. The sequence is repeated over successive time windows. Respective integrators 230a and 230 may be provided at the inputs to the respective phase shifters 152 and 153. Each integrator 230a and 230b operates in the manner described above with reference to the integrator 230 of FIG. 1A.

The first phase shifter 152 controls the phase difference between the first pair of RF power amplifiers 140a and 150a. The second phase shifter 153 controls the phase difference between the second pair of RF power amplifiers 140b and 150b. Each phase shifter 152 and 153 may operate, for example, in the manner of the phase shifter 151 of FIG. 1B or 3B, in which case respective clock generators 142a and 142b are provided at either (a) the top RF power amplifiers 140a and 150a respectively or (b) the bottom RF power amplifiers 140b and 150b respectively. The latter option (b) is depicted in FIG. 5A. Alternatively, each phase shifter 152 and 153 may function in the manner of the two port exciter or clock generator 340 of FIG. 4B, having a pair of clock outputs with a controllable phase difference between the pair of clock outputs, in which case the clock generators 142a and 142b are not present.

One advantage of the multiplexer 420 and the demultiplexer 425 is that a single feedback controller 210 controls the phase relationship for both RF frequencies F1 and F2.

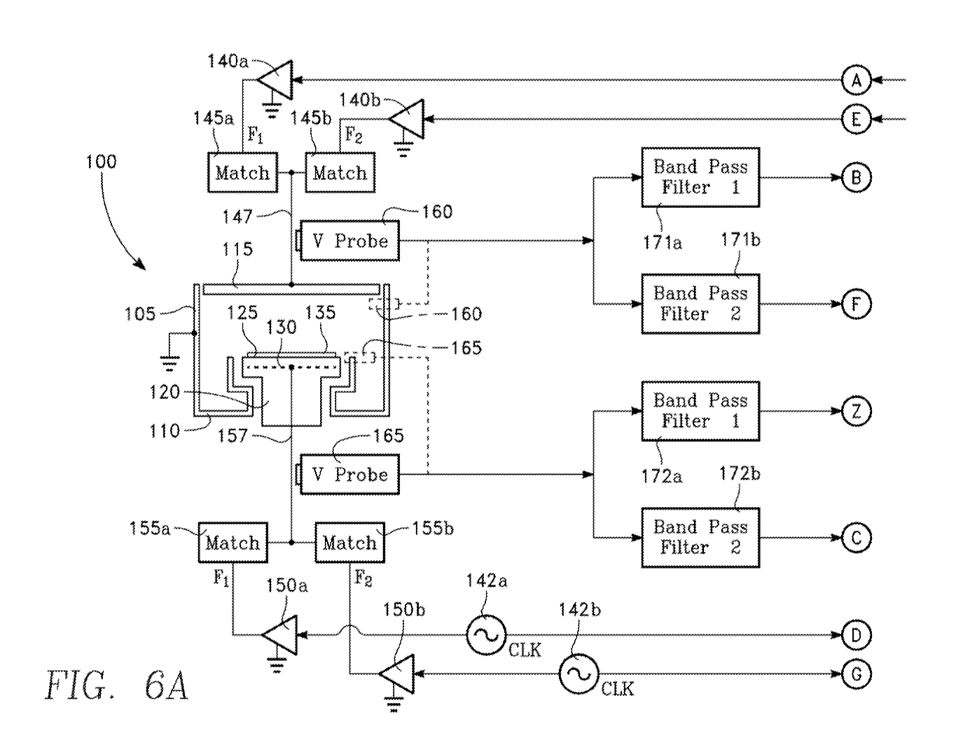

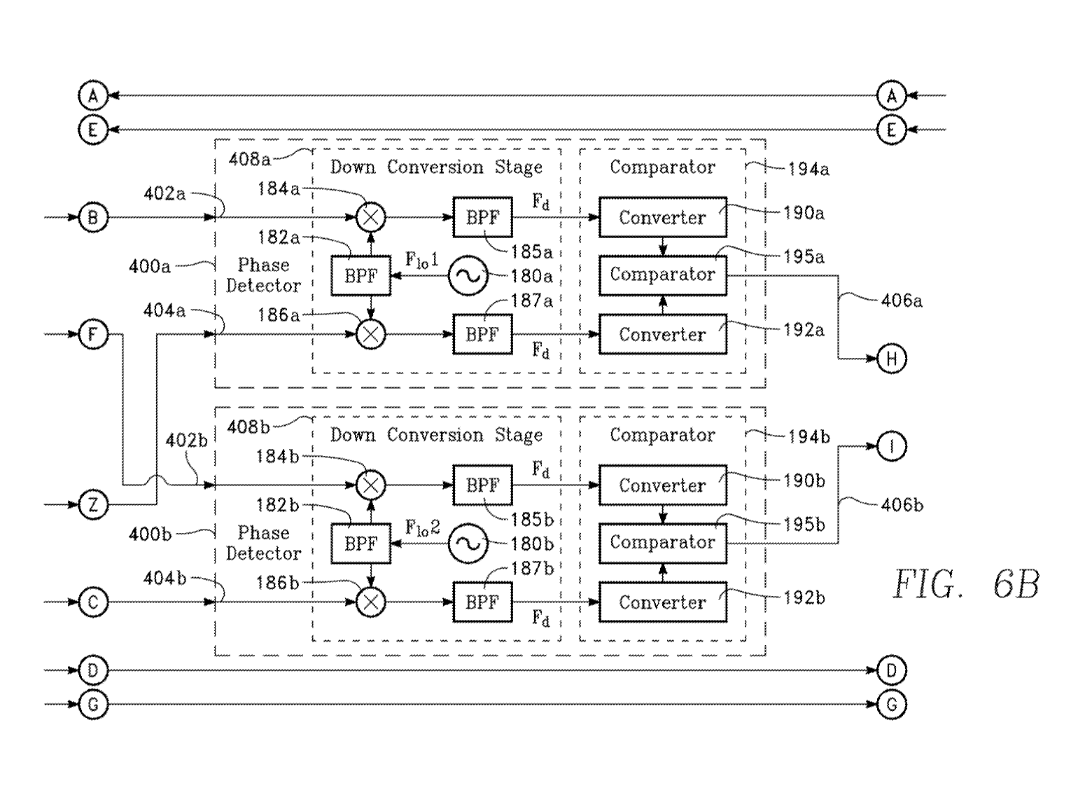

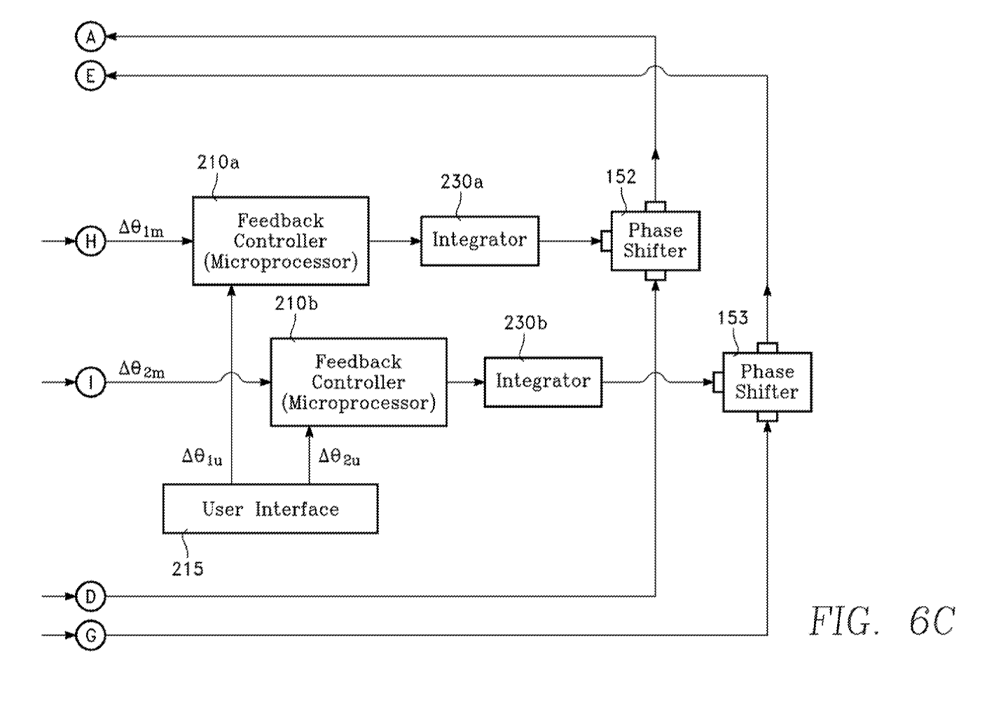

FIGS. 6A, 6B and 6C depict a modification of the embodiment of FIGS. 5A, 5B and 5C. In the embodiment of FIGS. 6A, 6B and 6C, multiplexing is not employed. Instead, a pair of feedback controllers 210a, 210b separately control the phase shifters 152 and 153, respectively, in response to the phase detectors 400a and 400b, respectively. The pair of feedback controllers 210a, 210b control independent feedback control loops.

Components of the foregoing embodiments may produce and/or receive signals in analog form. Thus for example, the output of the phase comparator 195 of FIG. 1A (or the phase comparators 195a and 195b of FIG. 5) may be an analog voltage. The output of the feedback controller 210 may also be an analog voltage. However, the foregoing components may be implemented as digital circuits that produce purely digital signals and perform digital implementations of the functions described above.

While the foregoing is directed to embodiments of the present invention, other and further embodiments of the invention may be devised without departing from the basic scope thereof, and the scope thereof is determined by the claims that follow.

What is claimed is:

1. A plasma reactor for processing a workpiece, comprising:
a vacuum chamber, an electrostatic chuck in said chamber and comprising an insulating puck having a workpiece support surface and a bottom electrode embedded in said puck under said workpiece support surface, a top electrode overlying said workpiece support surface, said top electrode comprising a gas distribution plate comprising an array of gas injection orifices;
top and bottom impedance matches, and top and bottom RF power amplifiers coupled, respectively, to said top and bottom electrodes through respective ones of said top and bottom impedance matches;
a clock signal source coupled to said top and bottom RF power generators, and a phase shifter coupled between said clock signal source and at least one of said top and bottom RF power generators, said phase shifter having a phase shifter control input;
top and bottom RF sensor probes coupled to said top and bottom electrodes, respectively;
a phase detector having respective inputs coupled to said top and bottom RF sensor probes and having an output;
a user interface having an output defining a user-selected phase difference between output signals of said top and bottom RF sensor probes;
a feedback controller having respective inputs coupled to said output of said phase detector and said output of said user interface, said feedback controller further having a feedback controller output coupled to said phase shifter control input.

2. The reactor of claim 1 wherein said phase detector comprises:
a frequency down conversion stage having respective inputs coupled to said RF sensor probes and respective outputs; and
a phase comparator having and output and a pair of inputs coupled to the respective outputs of said frequency down conversion stage.

3. The reactor of claim 1 further comprising an integrator coupled between said controller output and said phase shifter control input.

4. The reactor of claim 3 wherein:
said feedback controller is adapted to produce successive correction signals at said feedback controller output;
said integrator is adapted to provide to said phase shifter control input an average over n of the previous successive correction signals.

5. The reactor of claim 4 wherein n is an integer in a range up to 5.

6. The reactor of claim 4 wherein n is an integer in a range up to 100.

7. The reactor of claim 4 wherein n is an integer in a range up to 1000.

8. The reactor of claim 4 wherein said successive correction signals correspond to a sampling period T, and wherein T is less than a settling time of one of said impedance matches by a factor greater than 10.

9. The reactor of claim 2 wherein said phase comparator comprises:
respective sine wave-to-square wave converters coupled to said respective outputs of said frequency down conversion stage;
a phase lock loop phase comparator coupled to said respective sine wave-to-square wave converters.

10. The reactor of claim 2 wherein said phase comparator comprises an IQ demodulator.

11. A plasma reactor for processing a workpiece, comprising:
a vacuum chamber, an electrostatic chuck in said chamber and comprising an insulating puck having a workpiece support surface and a bottom electrode embedded in said puck under said workpiece support surface, a top electrode overlying said workpiece support surface, said top electrode comprising a gas distribution plate comprising an array of gas injection orifices;
first top and bottom RF power amplifiers coupled to said top and bottom electrodes respectively;
second top and bottom RF power amplifiers coupled to said top and bottom electrodes respectively;
a first clock signal scarce having a first common RF generator frequency and coupled to said first top and bottom RF power amplifiers, and a first phase shifter coupled between said first clock signal source and at least one of said first top and bottom RF power amplifiers, said first phase shifter having a first phase shifter control input;
a second clock signal source having a second common RF generator frequency and coupled to said second top and bottom RF power amplifiers, and a second phase shifter coupled between said second clock signal source and at least one of said second top and bottom RF power amplifiers, said second phase shifter having a second phase shifter control input;
top and bottom RF sensor probes coupled to said top and bottom electrodes, respectively;
a first phase detector having respective inputs coupled to said first top and bottom RF sensor probes and having a first output;
a second phase detector having respective inputs coupled to said second top and bottom RF sensor probes and having a second output;
a user interface having first and second outputs defining user-selected, phase differences between said first top and bottom RF sensor probes and between said second top and bottom RF sensor probes, respectively; and
a feedback controller having respective inputs coupled to the outputs of said first and second phase detector and said first and second outputs of said user interface, said feedback controller further having a feedback controller output coupled to said first and second phase shifter control inputs.

12. The reactor of claim 11 further comprising a multiplexer for multiplexing said feedback controller between (a) a first set of inputs comprising said first phase detector and said first user interface output and (b) a second set of inputs comprising said second phase detector and said second user interface output.

13. The reactor of claim 11 wherein:
said feedback controller comprises separate first and second feedback controllers;
said first feedback controller being coupled between (a) a first set of inputs comprising said first phase detector and said first user interface output and (b) said first phase shifter control input;
said second feedback controller coupled between (a) a second set of inputs comprising said second phase detector and said second user interface output and (b) said second phase shifter control input.

14. The reactor of claim 11 wherein each of said first and second phase detectors comprises:
a frequency down conversion stage having respective inputs coupled to said RF sensor probes and respective outputs; and
a phase comparator having and output and a pair of inputs coupled to the respective outputs of said frequency down conversion stage.

15. The reactor of claim 11 further comprising a first integrator coupled between said first controller and said first phase shifter control input and a second integrator coupled between said second controller and said second phase shifter control input.

16. The reactor of claim 15 wherein:
each of said feedback controllers is adapted to produce successive correction signals;
each of said integrators is adapted to provide to the corresponding phase shifter control input an average over n of the previous successive correction signals.

17. The reactor of claim 16 wherein said successive correction signals correspond to a sampling period T, and wherein T is less than a settling time of at least one of said impedance matches by a factor greater than 10.

18. The reactor of claim 14 wherein said phase comparator comprises:
respective sine wave-to-square wave converters coupled to said respective outputs of said frequency down conversion stage;
a phase lock loop phase comparator coupled to said respective sine wave-to-square wave converters.

19. The reactor of claim 14 wherein said phase comparator comprises an IQ demodulator.

20. The reactor of claim 16 wherein n is an integer of 5 or greater.
